(19) United States
(12) Patent Application Publication
(10) Pub. No.: US 2010/0330811 A1
(43) Pub. Date: Dec. 30, 2010

(54) Method for forming via holes

(75) Inventor: Takeshi Nagao, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/801,828

(22) Filed: Jun. 28, 2010

(30) Foreign Application Priority Data
Jun. 29, 2009 (JP) 2009-153854

(51) Int. Cl. H01L 21/306; H01L 21/465

(52) U.S. Cl. 438/737; 257/E21.577; 257/E21.219; 257/E21.485

(57) ABSTRACT

An improved method of forming a via hole is provided. This method makes it possible to form a via hole having a highly accurate processed shape in an insulating body. The insulating body has a multi-layer structure made of different kinds of insulating layers. The insulating body has, for example, a first insulating layer and a second insulating layer on the first insulating layer. The first insulating layer is provided on a lower wiring layer. The method includes a step of forming a first through hole in the second insulating layer by dry etching. The first through hole reaches the first insulating layer. The side wall of the first through hole defines an exposed portion of the second insulating layer. The bottom of the first through hole defines an exposed portion of the first insulating layer. The method also includes a step of assimilating the exposed portion of the second insulating layer and the exposed portion of the first insulating layer so that the exposed portions of the first and second insulating layers have the same composition. The method also includes a step of forming a second through hole extending from the first through hole to the lower wiring layer by dry etching. The first and second through holes defines a via hole. The via hole is made by removing the exposed portion of the first insulating layer.

### BACKGROUND OF THE INVENTION

1. Field of the Invention

The present invention relates to a method of forming a via hole that runs through an insulating film for establishing electrical connection with an electrode formed on a semiconductor substrate.

2. Description of Related Art

In recent years, the size of cellular phones is reduced and performances of the cellular phones are enhanced. Along with these changes, a camera module used in such cellular phone has more pixels and a lower profile. In addition, there is a demand for size reduction to sensor components used in the camera module of the cellular phone. While the wire bonding method, the flip chip method or the like has been conventionally employed for mounting the sensor components in the camera module, there has been an increased attention to a method that can mount the sensor component(s) in the form of CSP (Chip Scale Package or Chip Size Package). This method realizes high-density packaging since a sensor component has a micro size with a very small thickness, which is almost similar to the size of the chip itself. Also this method permits use of a conventional surface mount technique to mount sensors (or sensor components) on a printed circuit board. In this specification, such a sensor is hereinafter referred to as a “sensor CSP.”

There are many types of sensor CSPs. In one type of sensor CSP, for example, a wire is formed on a side surface of a package, and in another type a via hole, which is a through hole, is made in each of sensor CSPs (i.e., for each sensor chip). The latter type is called the TSV (Through Silicon Via) type. One example of the method for forming a via hole is described in Japanese Patent Application Kokai (Laid-Open) No. 2000-164566.

In order to decrease the wiring capacity and suppress the leak current, a two-layer insulation film is often employed that covers the wiring. This can improve the operation speed (operation frequency) and reliability of the semiconductor device. One method for forming a via hole in such two-layer insulation film is described in Japanese Patent Application Kokai No. 2001-77086.

### SUMMARY OF THE INVENTION

If a via hole is formed in a double-layer insulating film by means of dry etching, the resulting via hole often does not have a highly accurate shape due to the etching selectivity ratio between the insulating film and the wiring, a difference in the etching rate between a lower insulating layer (i.e., an insulator formed on the wiring) and an upper insulating layer, and a difference in the materials used for the lower insulating layer and the upper insulating layer.

More specifically, if the etching selectivity ratio between the insulating film and the wiring is small, the wiring is chipped off, and a part of the wiring (metal produced by the chipping) adheres to a side wall of the via hole. Thus, the opening size of the via hole does not have a desired value. If the etching selectivity ratio becomes large in order to avoid the above-described problem, the etching time becomes long. If the etching rate of the lower insulating layer is slower than that of the upper insulating layer, a side surface of the upper insulating layer may be etched during the etching of the lower insulating layer. As a result, the opening size of the via hole in the upper insulating layer becomes larger than the opening size of the via hole in the lower insulating layer. As such, it is difficult to form a via hole having a highly accurate shape.

One object of the present invention is to provide a method of forming a via hole having a highly accurate shape in a multi-layer insulating film.

According to a first aspect of the present invention, there is provided an improved method of forming a via hole that extends through a first insulating layer and a second insulating layer and reaches a lower wiring layer. The second insulating layer is provided on the first insulating layer so that the first and second insulating layers form a multi-layer insulating body. The first insulating layer is provided on the lower wiring layer. The second insulating layer has a different composition from the first insulating layer. The lower wiring layer is provided on a semiconductor substrate. The method includes forming a first through hole in the second insulating layer. The side wall of the first through hole defines an exposed portion of the second insulating layer. The first through hole extends to the first insulating layer so that part of the first insulating layer is exposed at the bottom of the first through hole. The method also includes assimilating the exposed portion of the first insulating layer and the exposed portion of the second insulating layer so that the exposed portions of the first and second insulating layers have the same composition. The method also includes forming a second through hole reaching the lower wiring layer from the first through hole by removing the exposed portion of the first insulating layer in the first through hole. The second through hole is continuous from the first through hole so that these through holes make a via hole. The second through hole extends downwards from the first through hole.

Since the assimilating step makes the exposed portions of the first and second insulating layers have the same composition in the first through hole, it is possible to suppress the stripping off of the lower layer wire and the receding of the first through hole during the formation of the second through hole. As a result, it is possible to form a via hole having a highly accurate processed shape in the multi-layer insulating body made of different kinds of insulating layers.

The first insulating layer may be made of silicon oxynitride and the second insulating layer may be made of silicon oxide. The assimilating step may include azotizing (nitriding) the exposed portion of the second insulating layer. The azotizing step may be performed by implanting nitrogen ions into the exposed portion of the second insulating layer. Alternatively, the azotizing step may be performed by a heating process using a gas containing at least a nitrogen atom.

The first insulating layer may be made of silicon oxynitride, and the second insulating layer may be made of silicon oxide. The assimilating step may include eliminating a nitrogen atom from the exposed portion of the first insulating layer. The eliminating step may be performed by a heating process using dinitrogen oxide.

A cross-section of the via hole may be circular, and a diameter of the circular cross-sectional shape may unchange in a depth direction of the via hole. Alternatively, the diameter of the circular cross-sectional shape may decrease in the depth direction of the via hole.

The first through hole forming step may be carried out by dry etching. The via hole forming step may also be carried out by dry etching. These two dry etching processes may be carried out under the same etching condition.

These and other objects, aspects and advantages of the present invention will become apparent to those skilled in the art from the following detailed description when read and understood in conjunction with the appended claims and drawings.

### BRIEF DESCRIPTION OF THE DRAWINGS

FIGS. 1A-1D, FIGS. 2A-2C and FIGS. 3A-3C are a series of cross-sectional views respectively showing steps of a semiconductor device manufacturing method that includes a via hole making method according to Embodiment 1 of the present invention.

FIGS. 4A-4C and FIGS. 5A-5C are a series of cross-sectional views respectively showing steps of the semiconductor device manufacturing method that includes a via hole making method according to Embodiment 2 of the present invention.

### DETAILED DESCRIPTION OF THE INVENTION

Embodiments of the present invention will be described in detail with reference to the accompanying drawings.

### EMBODIMENT 1

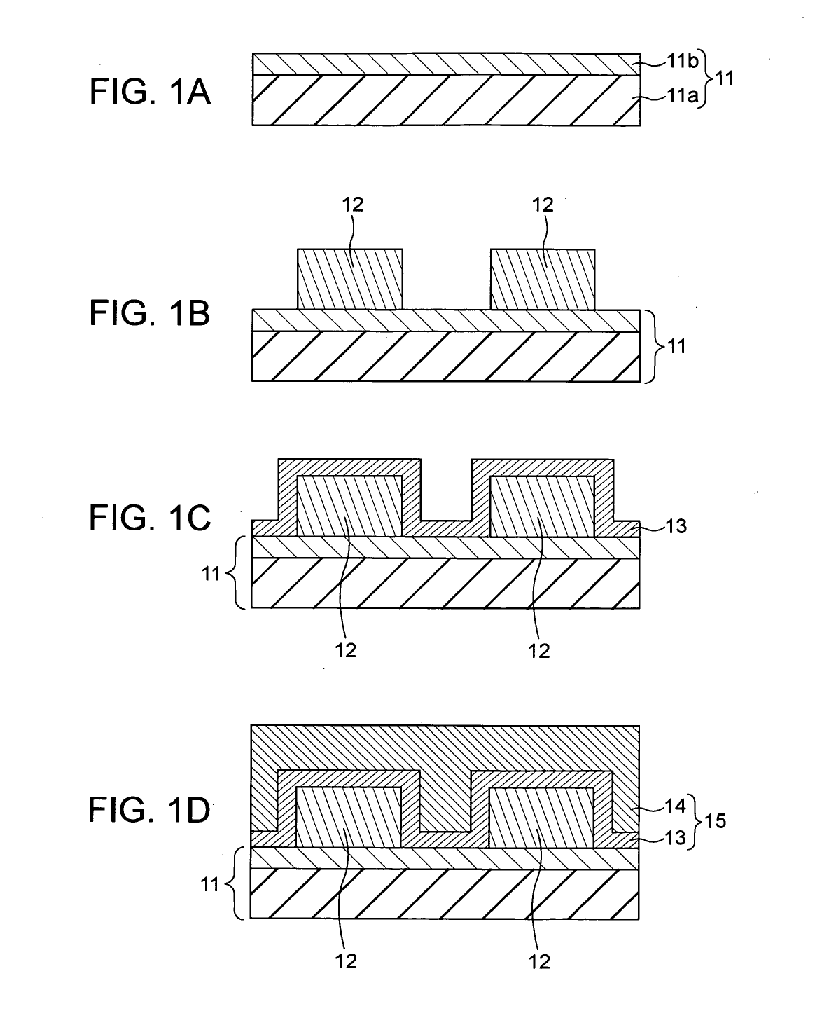

Referring to FIG. 1A to FIG. 3C, a first exemplary method of forming a via hole according to the present invention will be described.

First, an 8-inch semiconductor element substrate 11 is prepared (FIG. 1A). The semiconductor element substrate 11 includes a silicon substrate 11a made of silicon (Si) and a semiconductor element layer 11b formed on the silicon substrate 11a . The semiconductor element layer 11b has a drain region, a drain electrode, a source region, a source electrode, a gate insulating film, a gate electrode, a device separation region, and an insulating film covering the above-mentioned regions, electrodes and film. It should be noted that in the drawings the individual elements forming the semiconductor element layer 11b are omitted for the sake of simplicity.

Next, lower layer wiring 12 with a desired shape is formed on the semiconductor element substrate 11 (FIG. 1B). More specifically, copper is deposited on the semiconductor element substrate 11 by sputtering. Then, a resist is applied on the deposited copper, and desired patterning is performed on the resist by photolithography. The patterned resist is used as a mask in an etching process. Dry etching is performed with the patterned resist (or the mask) to form the lower layer wiring 12 having a desired shape. The resist is removed after forming the lower layer wire 12. The lower layer wiring 12 is connected to the drain electrode, the source electrode, and the gate electrode of the semiconductor element layer 11b.

A first insulating layer (lower insulating layer) 13 is formed by the thermal CVD method, which is the chemical vapor deposition method using a thermal energy, so as to cover the main surface (upper surface) of the semiconductor element substrate 11 and the lower layer wire 12 (FIG. 1C). The first insulating layer 13 is made of silicon oxynitride (SiON). A second insulating layer (upper insulating layer) 14 is formed over the first insulating layer 13 by means of plasma CVD method which is the CVD method using a plasma energy (FIG. 1D). The second insulating layer 14 is made of silicon oxide (SiO). Accordingly, there is obtained a two-layer insulator 15 constituted by the two kinds of insulators having different compositions. It should be remembered that the first insulating layer 13 has a slower etching rate than the second insulating layer 14 in a subsequent etching process using an etching gas (will be described later). Thus, the etching proceeds slower in the first insulating layer 13 than in the second insulating layer 14.

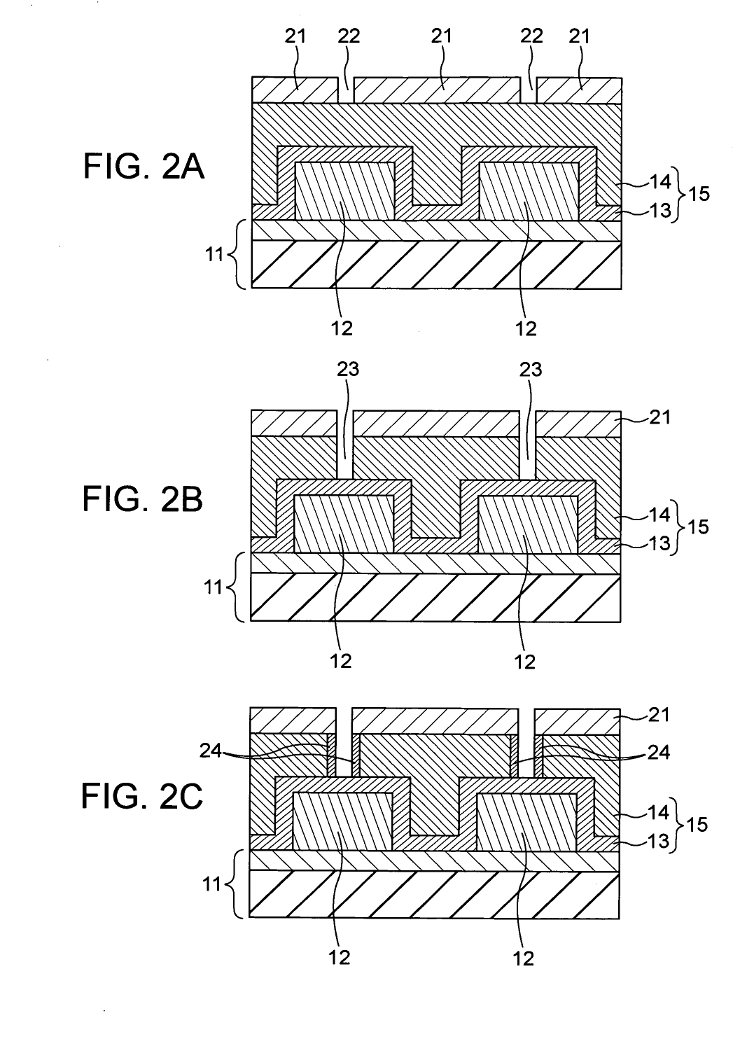

Referring to FIG. 2A, a resist 21 is applied onto the multi-layer insulating body 15, and desired patterning is performed on the resist 21 by means of photolithography so that openings 22 are formed in the resist 21.

A plurality of first through holes 23 that pass through the second insulating layer 14 from the associated openings 22 are formed by dry etching (FIG. 2B). The horizontal cross-sectional shape of each first through hole 23 is circular. The first through holes 23 reach the boundary between the first insulating layer 13 and the second insulating layer 14. The specific etching conditions are as follow. C₄F₈, O₂ and Ar are used as etching gases. The flow rates of the etching gases are 20 sccm (standard cc/min) for C₄F₈, 12 sccm for O₂, and 500 sccm for Ar. The etching time is 100 seconds, and the pressure is 40 millitorrs (mTorr). The power of a high frequency power source (RF Power) is 1700 watts (W), and the temperature is about 50 to 60 degrees Celsius (50° C. to 60° C.). This etching is the anisotropic etching. Since the anisotropic etching technique is used in this embodiment, the opening size of each first through hole 23 is almost identical to the opening size of the associated opening 22. The etching progresses in the thickness direction of the second insulating layer 14, but the etching hardly progresses in the direction perpendicular to the thickness direction.

Exposed portions of the second insulating layer 14 by the first through holes 23 (that is, side wall of each first through hole 23) are azotized (nitrided) by a known oblique incident ion implantation method. As a result, a protecting film 24 made of SiON is formed in the side wall of each first through hole 23 (FIG. 2C). More specifically, while the semiconductor element substrate 11 with the multi-layer insulator 15 is subjected to a heating process at about 400° C., nitrogen ions are injected into the exposed portions of the second insulating layer 14 at an acceleration energy of about 10 to several hundreds of electron volts (eV) and at a dose of about 1×10¹⁵ cm⁻² to 1×10¹⁸ cm⁻². The thickness of the protecting film 24 (the thickness in the direction perpendicular to the thickness direction of the second insulating layer 14) is, for example, in the range of 30 to 60 nanometers (nm). If the heating temperature is over 400° C., the lower layer wire 12 might be affected by the heating. Thus, it is preferred to set the heating temperature to 400° C. or lower. Through this step, the exposed portions of the second insulating layer 14 are transformed to insulators made of SiON which have the same composition as that of the first insulating layer 13. As a result, SiO is not exposed in each first through hole 23. In this specification, this step is referred to as an “assimilation step.” The protecting film 24 is a film made by the assimilation step. Thus, the protecting film 24 may be referred to as an assimilated portion of the second insulating layer 14.

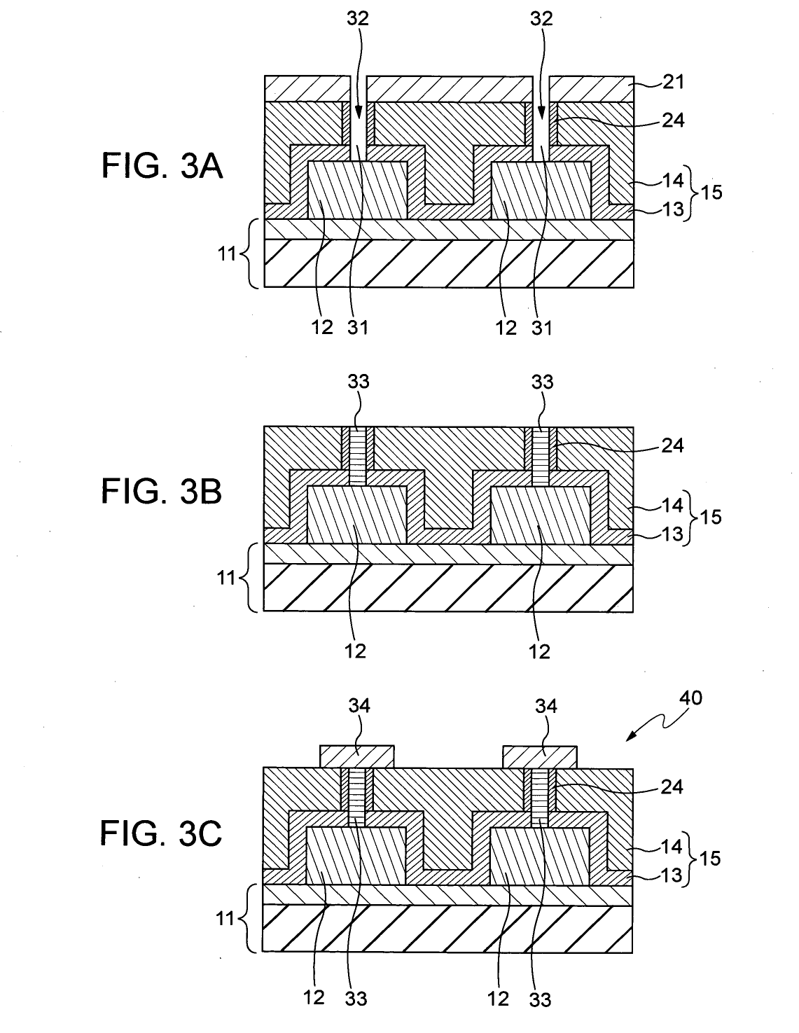

Referring now to FIG. 3A, a second through hole 31 passing through the first insulating layer 13 from each first through hole 23 is formed by dry etching. This etching is the anisotropic etching. Each second through hole 31 reaches the boundary between the lower layer wire 12 and the first insulating layer 13. The dry etching conditions in this step are set so that the etching selectivity ratio between the lower layer wire 12 and the multi-layer insulator 15 is smaller than that in the dry etching condition in the step of forming the first through holes 23. This setting prevents the lower layer wire 12 from being chipped off during the etching of FIG. 3A, and prevents the resultant metal particles, which would otherwise be created, from being attached to the second insulating layer 14. Since the entire surfaces exposed by the first through holes 23 are insulators made of SiON (i.e., the first insulating layer 13 and the protecting film 24), etching will not progress in the direction perpendicular to the thickness direction of the multi-layer insulator 15 even when the etching time is long. Thus, the opening size of the first through hole 23 is not increased.

The specific etching conditions in the step of FIG. 3A are as follow. C₄F₈, O₂ and Ar are used as etching gases. The flow rates of the etching gases are 20 sccm for C₄F₈, 7 sccm for O₂, and 500 sccm for Ar. The etching time is 45 seconds, and the pressure is 40 mTorr. The power of a high frequency power source is 1700 W, and the temperature is about 40° C. to 60° C. These etching conditions also can suppress the enlargement of the opening size of each opening 22 in the resist 21. In other words, the receding of the resist 21 can be avoided.

Since the anisotropic etching technique is used to create the second through holes 31, the opening size of each second through hole 31 is almost identical to the opening size of the associated first through hole 23. That is, the etching progresses in the thickness direction of the first insulating layer 13, but the etching hardly progresses in the direction perpendicular to the thickness direction. The completion of the step of FIG. 3A allows for the communication between the first through holes 23 and the second through holes 31, thereby forming a plurality of via holes 32 constituted by the first and second through holes 23 and 31. The diameter of each via hole 32 does not change for the entire height (depth) of the via hole.

The resist 21 is removed. Subsequently, tungsten (W) is filled into each via hole 32 by CVD to form a contact plug 33 in each via hole 32, as shown in FIG. 3B. It should be noted that after filling tungsten, the second insulating layer 14 and the contact plug 33 may be flattened by using the CMP (Chemical Mechanical Polishing) method.

An upper layer wire 34 having a desired shape is formed on the second insulating layer 14, as shown in FIG. 3C. More specifically, copper is deposited on the second insulating layer 14 by means of sputtering. Next, a resist is applied on the deposited copper. Desired patterning is performed on the resist by means of photolithography. Dry etching is performed with the patterned resist using as a mask to form the upper layer wire 34 having a desired shape. The resist is removed after forming the upper layer wire 34. Through all the steps, a semiconductor device 40 is obtained.

As described above, the above-described method according to the first embodiment can form a plurality of via holes 32 penetrating through the first insulating layer 13 covering the lower layer wire 12 formed on the semiconductor substrate 11 and the second insulating layer 14 covering the first insulating layer 13 and having a composition different from that of the first insulating layer such that the via holes 32 reach the lower layer wire 12. The method includes the step of forming the first through holes in the second insulating layer by dry etching; the step of assimilating those portions of the first and second insulating layers which are exposed by the first through holes so as to obtain insulators having the same composition in the first through holes; and the step of forming the second through holes reaching the lower layer wire by removing the exposed portions of the first insulating layer by means of dry etching. The second through holes are continuous from the corresponding first through holes.

The method includes the assimilation step of making the portions of the first and second insulating layers exposed by the first through holes 23 into insulators having the same composition. Thus, it is possible to suppress the stripping off of the lower wiring layer 12 and the receding of the first through holes 23 during the formation of the second through holes 31. As a result, it is possible to form via holes 32 having a highly accurate processed shape in the multi-layer insulating film 15 having different kinds of insulating layers 13 and 14. It is also possible to suppress the receding of the resist mask.

Although the diameter of each via hole 32 has a fixed value for its entire height in the first embodiment, the etching conditions may be changed so that the diameter (opening size) of the via hole 32 gradually decreases toward the lower wiring layer 12 (that is, the via hole 32 may have a tapered side wall). This configuration facilitates the ion implantation that is performed when making the protecting film 24 in the side wall of each via hole 32.

While the oblique incident ion implantation method is employed to form the protecting film 24 in the first embodiment, the present invention is not limited in this regard. For example, the protecting film 24 may be formed by performing a predetermined heating process while introducing nitrogen gas, a mixed gas of nitrogen and hydrogen, or ammonia gas.

Although the resist 21 is removed after forming the via holes 32 in the illustrated embodiment, the resist 21 may be removed after forming the first through holes 23 (between FIG. 2B and FIG. 2C). If the resist 21 is removed prior to FIG. 2C, the ion implantation to be performed for making the protecting film 24 is facilitated.

### EMBODIMENT 2

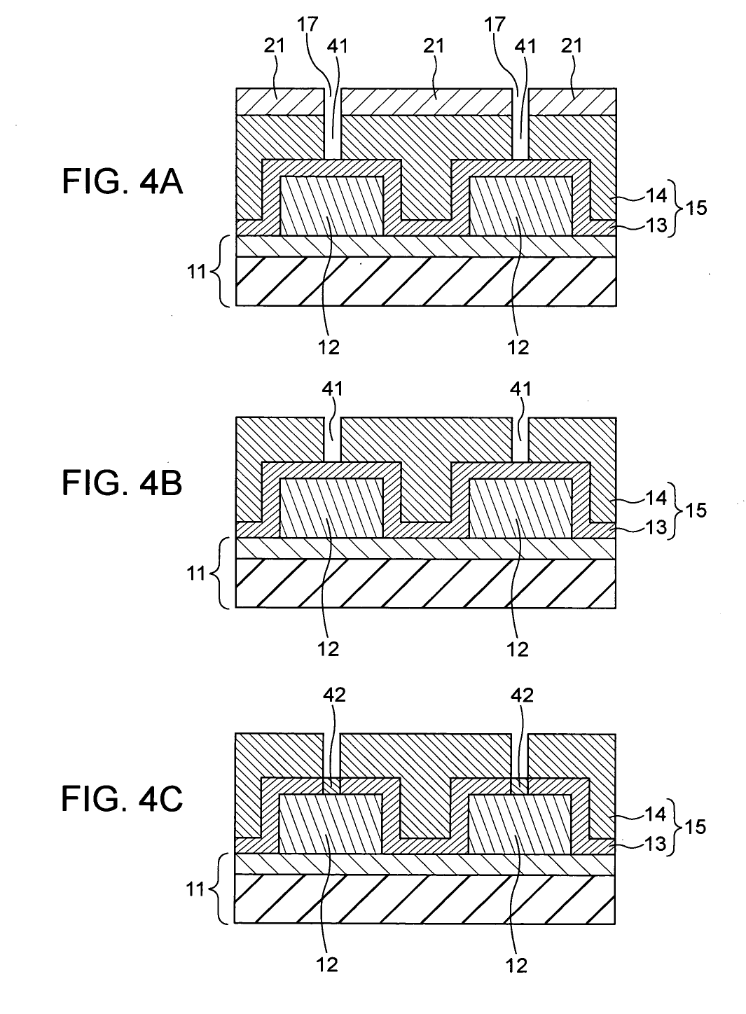

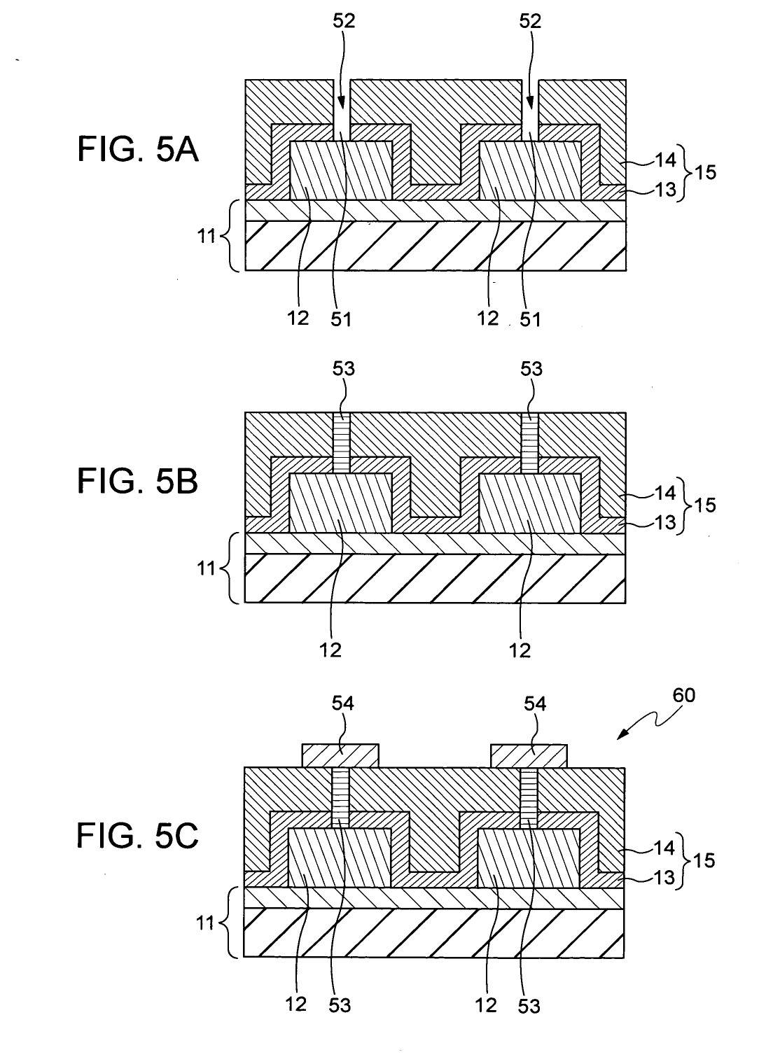

In Embodiment 1, SiO exposed by each first through hole 23 (i.e., exposed part of the second insulating layer 14) is azotized to form the protecting film 24 made of SiON, thereby making the entire surfaces exposed by the first through hole 23 (i.e., the side and bottom walls of each first through hole 23) into insulators having the same composition. The present invention is not limited in this regard. Specifically, nitrogen may be removed from SiON that is exposed at the bottom of each first through hole 23 (exposed part of the first insulating layer 13) to form an insulator made of SiO, thereby making the entire exposed surfaces of each first through hole 23 into insulators having the same composition (SiO). A method of forming via holes in such a modification will be described in detail with reference to FIG. 4A to FIG. 5C. It should be noted that the same elements as those of Embodiment 1 will be designated by the same reference numerals and symbols, and the description thereof will be omitted.

Since the steps of forming, on the semiconductor element substrate 11, the lower wiring layer 12, the first insulating layer 13, the second insulating layer 14, and the resist 21 are the same as those shown in FIG. 1A to FIG. 2A, the description thereof will be omitted.

After forming the insulator 15 having a two-layer structure made of the first insulating layer 13 and the second insulating layer 14, a plurality of first through holes 41 extending through the second insulating layer 14 are formed by dry etching (FIG. 4A). The first through holes 41 reach the boundary between the first insulating layer 13 and the second insulating layer 14. The etching conditions are as follow. C₄F₈, O₂ and Ar are used as etching gases. The flow rates of the etching gases are 20 sccm for C₄F₈, 12 sccm for O₂, and 500 sccm for Ar. The etching time is 20 seconds, and the pressure is 40 mTorr. The power of a high frequency power source is 1700 W, and the temperature is about 50° C. to 60° C. This dry etching is the anisotropic etching. Because the anisotropic etching technique is used, the opening size of each first through hole 41 is almost identical to the opening size of the corresponding opening 17. That is, the etching progresses in the thickness direction of the second insulating layer 14, but the etching hardly progresses in the direction perpendicular to the thickness direction.

The resist 21 is removed (FIG. 4B). Subsequently, nitrogen atoms are eliminated from the exposed portions of the first insulating layer 13 at the bottoms of the first through holes 41 by means of the heating process using a plasma CVD apparatus so as to form a third insulating layer 42 made of SiO in each first through hole 41 (FIG. 4C). In this step, nitrogen atoms that exist from the exposed surface of the first insulating layer 13 to the boundary between the first insulating layer 13 and the lower wiring layer 12 are eliminated, thereby forming only the third insulating layer 42 at the bottom of each first through hole 41. The reason why such a reaction occurs is because the substitution between a nitrogen atom of SiON and an oxygen atom of N₂O occurs in the exposed portion of the first insulating layer 13 positioned at the bottom of each first through hole 41 by performing the heating process using dinitrogen oxide (N₂O), thereby resulting in the elimination of a nitrogen atom from SiON. The specific conditions for the heating process are as follow. The gas used is N₂O, the power of a shortwave power source (HF POWER) is 40 W, the temperature is 1700° C., the pressure is 20 Torr, and the processing time is 20 seconds. It should be noted that the above-mentioned conditions allows for the elimination of nitrogen atoms in the thickness of about 30 nm to about 60 nm. Therefore, when the thickness of the first insulating layer 13 is greater than 60 nm, the processing time is changed to over 20 seconds, and when the thickness of the first insulating layer 13 is less than 30 nm, the processing time is changed to less than 20 seconds. Through this step, the exposed portion of the first insulating layer 13 is transformed to an insulator made of SiO that is the same composition as that of the second insulating layer 14. As a result, SiON is not exposed in the first through holes 41. This step is referred to as an “assimilation step.”

Referring now to FIG. 5A, a plurality of second through holes 51 passing through the first insulating layer 13 are formed by dry etching (FIG. 5A). This etching is anisotropic etching. The second through holes 51 extend (or continue) downwards from the corresponding first through holes 41, respectively. The second through holes 51 reach the boundary between the lower wiring layer 12 and the first insulating layer 13. The specific etching conditions are the same as those in the step of forming the first through holes 41. The reason why the same etching conditions can be used is because the insulator exposed at the bottom of each first through hole 41 is made of SiO that is the same composition as that of the second insulating layer 14. As such, the etching processing time can be shortened as compared to a conventional etching processing time.

Since the anisotropic etching technique is used in this embodiment, the opening size of each second through hole 51 is almost identical to the opening size of the corresponding first through hole 41. That is, the etching progresses in the thickness direction of the first insulating layer 13, but the etching hardly progresses in the direction perpendicular to the thickness direction. The completion of this step allows for the communication between the first through holes 41 and the corresponding second through holes 51, thereby forming a plurality of via holes 52 constituted by the first and second through holes 41 and 51.

Tungsten is filled into each via hole 52 by CVD to form a contact plug 53 (FIG. 5B). It should be noted that after filling tungsten, the second insulating layer 14 and the contact plug 53 may be flattened by using the CMP method.

An upper layer wire 54 with a desired shape is formed on the two-layer insulation body 15 (FIG. 5C). More specifically, copper is deposited on the two-layer insulation body 15 by means of sputtering. Next, a resist is applied on the deposited copper. Desired patterning is performed on the resist by means of photolithography. Dry etching is performed with the patterned resist using as a mask to form the upper layer wire 54 having a desired shape. The resist is removed after forming the upper layer wire 54. Through all these steps, a semiconductor device 60 is completed.

As described above, since etching can be performed for the first through holes and the second through holes under the same etching condition, the time required to form the via holes can be further shortened in this embodiment.

It should be noted that although the resist 21 is removed before the step of eliminating nitrogen atoms in Embodiment 2, the resist 21 may be removed after the elimination of nitrogen atoms by lowering the heating temperature in the step of eliminating nitrogen atoms.

This application is based on Japanese Patent Application No. 2009-153854 filed on Jun. 29, 2009 and the entire disclosure thereof is incorporated herein by reference.

What is claimed is:

1. A method of forming a via hole passing through an upper insulating layer and a lower insulating layer and reaching a lower wiring layer, the upper insulating layer being provided on the lower insulating layer, the lower insulating layer being provided on the lower wiring layer, the lower wiring layer being provided on a semiconductor substrate, and the upper insulating layer having a composition different from that of the lower insulating layer, the method comprising:
forming a first through hole in the upper insulating layer such that the first through hole reaches the lower insulating layer, with a portion of the lower insulating layer being exposed at a bottom of the first through hole and a portion of the upper insulating layer being exposed by a side wall of the first through hole;
assimilating the exposed portion of the upper insulating layer and the exposed portion of the lower insulating layer so that the exposed portion of the upper insulating layer has the same composition as the exposed portion of the lower insulating layer; and
forming a second through hole extending to the lower wiring layer from the first through hole by removing the exposed portion of the lower insulating layer so that the via hole is made by the first and second through holes.

2. The method according to claim 1, wherein the lower insulating layer is made of silicon oxynitride, the upper insulating layer is made of silicon oxide, and said assimilating includes nitriding the exposed portion of the upper insulating layer.

3. The method according to claim 2, wherein said nitriding the exposed portion of the upper insulating layer is performed by implanting nitrogen ions into the exposed portion of the upper insulating layer.

4. The method according to claim 2, wherein said nitriding the exposed portion of the upper insulating layer is performed by a heating process using a gas containing at least a nitrogen atom.

5. The method according to claim 1, wherein the lower insulating layer is made of silicon oxynitride, the upper insulating layer is made of silicon oxide, and said assimilating includes eliminating a nitrogen atom from the exposed portion of the lower insulating layer.

6. The method according to claim 5, wherein said eliminating a nitrogen atom is performed by a heating process using dinitrogen oxide.

7. The method according to claim 1, wherein a cross-section of the via hole is circular, and a diameter of the circular cross-sectional shape decreases in a depth direction of the via hole.

8. The method according to claim 1, wherein a cross-section of the via hole is circular, and a diameter of the circular cross-sectional shape is unchanged in a depth direction of the via hole.

9. The method according to claim 1, wherein said forming a first through hole is carried out by first dry etching, and said forming the second through hole is carried out by second dry etching.

10. The method according to claim 9, wherein the first dry etching is anisotropic etching and the second dry etching is also anisotropic etching.

11. The method according to claim 3, wherein said implanting nitrogen ions into the exposed portion includes oblique incident ion implantation.

12. The method according to claim 4, wherein said heating is carried out at a temperature of 400 degrees C. or below.

13. The method according to claim 10, wherein the second dry etching has a smaller etching selectivity ratio than the first dry etching with respect to the lower wiring layer.

14. The method according to claim 10, wherein the second dry etching is carried out under same etching conditions as the first dry etching.

15. The method according to claim 10, wherein the second dry etching is carried out under different etching conditions from the first dry etching.
